(19) United States
(12) Patent Application Publication
(10) Pub. No.: US 2025/0048794 A1
(43) Pub. Date: Feb. 6, 2025

(54) MICRO LED, MICRO LED DISPLAY PANEL, AND EPITAXIAL STRUCTURE

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 18/788,188

(22) Filed: Jul. 30, 2024

(30) Foreign Application Priority Data
Jul. 31, 2023 (WO) PCT/CN2023/110277

(51) Int. Cl. H01L 33/30; H01L 25/075; H01L 33/02; H01L 33/06; H01L 33/46; H01L 33/62

(52) U.S. Cl. CPC H01L 33/30; H01L 25/0753; H01L 33/025; H01L 33/06; H01L 33/46; H01L 33/62

(57) ABSTRACT

A micro LED includes a bonding layer, an N type semiconductor layer formed on the bonding layer; a light emitting layer formed on the N type semiconductor layer, a P type semiconductor layer formed on the light emitting layer, and a top conductive layer formed on the P type semiconductor layer.

### CROSS-REFERENCE TO RELATED APPLICATIONS

The present disclosure claims the benefits of priority to PCT Application No. PCT/CN2023/110277, filed on Jul. 31, 2023, which is incorporated herein by reference in its entirety.

### TECHNICAL FIELD

The present disclosure generally relates to micro LED manufacturing technology, and more particularly, to a micro LED, a micro LED display panel, and an epitaxial structure.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) backplane. Each pixel of the micro LED display panel is formed by one or more micro LEDs. The micro LED display panel can be a mono-color or multi-color panel. In particular, for a multi-color LED panel, each pixel may further include multiple sub-pixels respectively formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges. For example, with a smaller size of a micro LED, a shading effect becomes more serious, which may impact the light emission efficiency.

### SUMMARY OF THE DISCLOSURE

Embodiments of the present disclosure provide a micro LED. The micro LED includes a bonding layer, an N type semiconductor layer formed on the bonding layer; a light emitting layer formed on the N type semiconductor layer; a P type semiconductor layer formed on the light emitting layer; and a top conductive layer formed on the P type semiconductor layer.

Embodiments of the present disclosure also provide a micro LED display panel. The micro LED display panel includes an integrated circuit (IC) backplane comprising a bottom pad array, the bottom pad array comprising a plurality of conductive bottom pads; and a micro LED array formed on the IC backplane, the micro LED array including a plurality of above described micro LEDs. One micro LED of the plurality of micro LEDs is electrically connected with one bottom pad of the plurality of conductive bottom pads.

Embodiments of the present disclosure provide an epitaxial structure for a micro LED. The epitaxial structure includes a substrate; an etch stop layer formed on the substrate; a P type epitaxial layer formed on the etch stop layer; a light emitting layer formed on the P type epitaxial layer; and an N type epitaxial layer formed on the light emitting layer.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing an exemplary micro LED, according to prior art.

FIG. 2 illustrates a structural diagram showing an exemplary micro LED, according to some embodiments of the present disclosure.

FIG. 3 illustrates a structural diagram showing further details of the exemplary micro LED illustrated in FIG. 2, according to some embodiments of the present disclosure.

FIG. 4 illustrates a structural diagram showing an exemplary micro LED, according to some embodiments of the present disclosure.

FIG. 5 illustrates a structural diagram showing an exemplary micro LED, according to some embodiments of the present disclosure.

FIG. 6 illustrates a structural diagram showing an exemplary micro LED, according to some embodiments of the present disclosure.

FIG. 7 illustrates a structural diagram showing an exemplary micro LED, according to some embodiments of the present disclosure.

FIG. 8 illustrates a structural diagram showing a top view of an exemplary micro LED display panel, according to some embodiments of the present disclosure.

FIG. 9 illustrates a structural diagram showing an exemplary epitaxial structure, according to some embodiments of the present disclosure.

FIG. 10 illustrates a structural diagram showing sub-layers of the exemplary epitaxial structure shown in FIG. 9, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

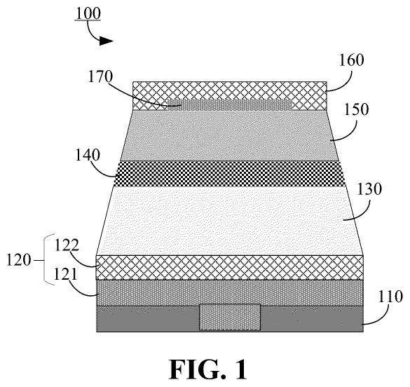

FIG. 1 illustrates a structural diagram showing an exemplary micro LED 100. As shown in FIG. 1, micro LED 100 has an N-side up structure provided on an IC backplane 110. Micro LED 100 includes a bonding layer 120, a P type semiconductor layer 130, a light emitting layer 140, an N type semiconductor layer 150, and a top conductive layer 160 from bottom to top. Bonding layer 120 includes a metal bonding layer 121 and a transparent conductive layer 122. An N-metal layer 170 is further provided between N type semiconductor layer 150 and top conductive layer 160 for providing ohmic contact. With this structure, with a size of micro LED 100 becoming smaller and smaller, a shading effect caused by N-metal layer 170 may become serious.

In order to resolve a potential shading problem caused by N-metal layer 170, embodiments of the present disclosure provide micro LEDs with a P-side up structure.

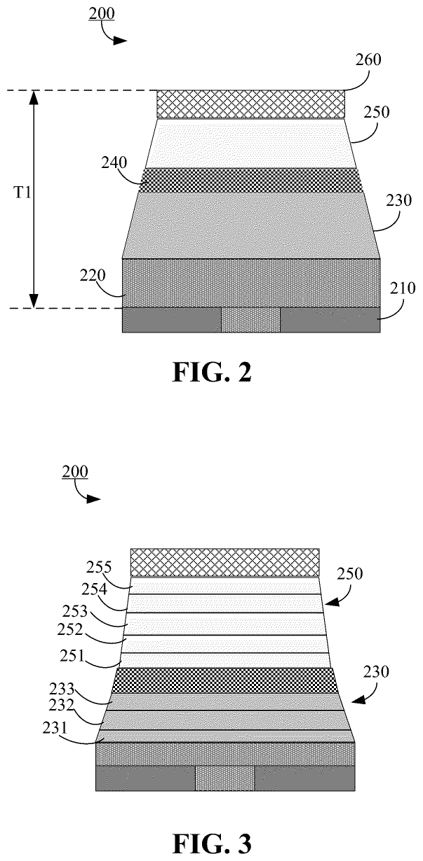

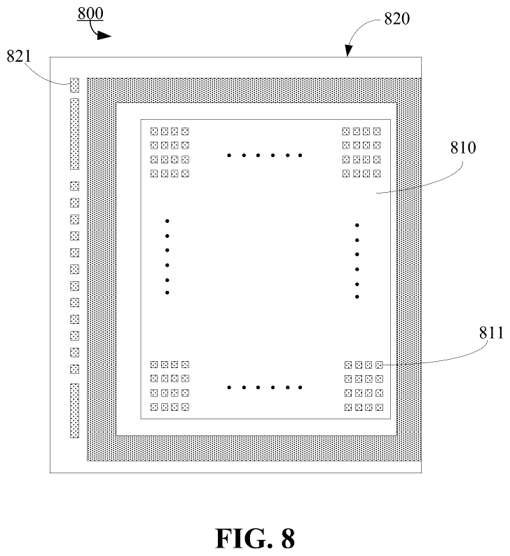

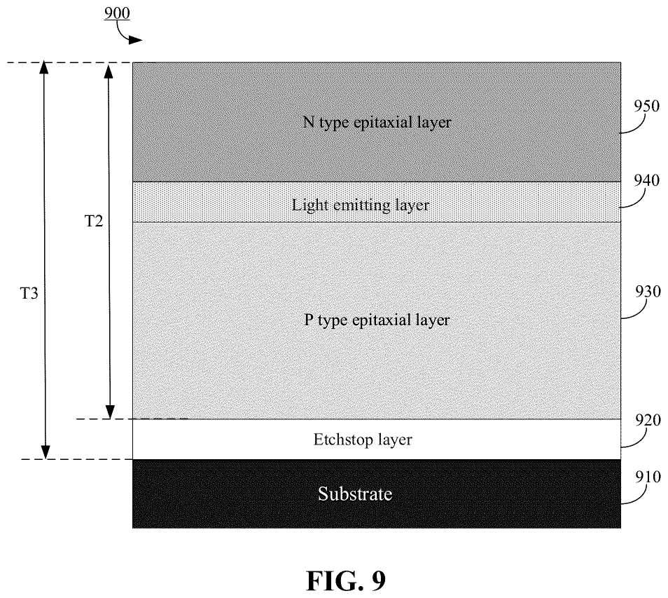

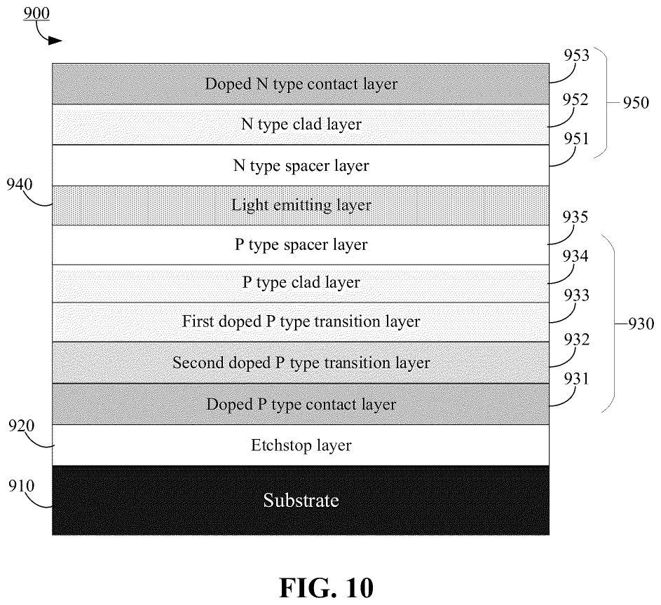

FIGS. 2-7 illustrate various features and variations of micro LEDs having a P-side up structures, FIG. 8 illustrates a micro displaying panel incorporating such micro LEDs, and FIGS. 9 and 10 illustrate an epitaxial structure consistent with aspects of fabricating such micro LEDs.

FIG. 2 illustrates a structural diagram showing an exemplary micro LED 200, according to some embodiments of the present disclosure. As shown in FIG. 2, micro LED 200 with a P-side up structure includes a bonding layer 220 and an N type semiconductor layer 230 provided on bonding layer 220. Bonding layer 220 is used to bond N type semiconductor layer 230 with an IC backplane 210. A light emitting layer 240 is formed on N type semiconductor layer 230. A P type semiconductor layer 250 is formed on light emitting layer 240. A top conductive layer 260 is formed on P type semiconductor layer 250. Different from micro LED 100 shown in FIG. 1, P type semiconductor layer 250 is contacted with top conductive layer 260. Since P type semiconductor layer 250 can easily form an ohmic contact with top conductive layer 260, there is no need to have a metal layer between P type semiconductor layer 250 and top conductive layer 260 to provide the ohmic contact. Therefore, the shading effect caused by metal can be obviated.

In some embodiments, light emitting layer 240 includes at least one quantum well layer. A thickness of the quantum well layer is from 20 nm to 40 nm, for example, 30 nm. In some embodiments, a material of the quantum well layer is GaInP/(AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, light emitting layer 240 is a multiple quantum well (MQW).

FIG. 3 illustrates a structural diagram showing further details of the exemplary micro LED 200 illustrated in FIG. 2, according to some embodiments of the present disclosure. As shown in FIG. 3, N type semiconductor layer 230 further includes a doped N type contact layer 231, an N type cladding layer 232, and an N type spacer layer 233 from bottom to top. In some embodiments, a material of doped N type contact layer 231 is GaAs. In some embodiments, a thickness of doped N type contact layer 231 is from 10 nm to 30 nm. A doping concentration of doped N type contact layer 231 is from 2e¹⁸ cm⁻³ to 1e¹⁹ cm⁻³.

In some embodiments, a material of N type cladding layer 232 is AlₓIn₁₋ₓP, where a range of x is from 0.1 to 0.5, for example, x is 0.5. Further, in such embodiments, a thickness of N type cladding layer 232 is not greater than 350 nm, for example, the thickness of N type cladding layer 232 is 320 nm. A doping concentration of N type cladding layer 232 is from 5e¹⁷ cm⁻³ to 1e¹⁸ cm⁻³.

In some embodiments, a material of N type spacer layer 233 is (AlₓGa₁₋ₓ)_{y}In_{1-y}P, where a range of x is from 0.5 to 0.9, and a range of y is from 0.1 to 0.5. For example, x is 0.8, and y is 0.5. In some embodiments, a relationship between x and y is that x is 1 to 2 times y. A thickness of N type spacer layer 233 is from 50 nm to 75 nm, for example, 65 nm.

Still referring to FIG. 3, P type semiconductor layer 250 includes a P type spacer layer 251, a P type cladding layer 252, a first doped P type transition layer 253, a second doped P type transition layer 254, and a doped P type contact layer 255 from bottom to top. In some embodiments, a material of P type spacer layer 251 is (AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, a thickness of P type spacer layer 231 is from 50 nm to 70 nm, for example, 65 nm.

In some embodiments, a material of P type cladding layer 252 is AlₓIn₁₋ₓP, where x is from 0.3 to 0.5, for example, x is 0.5. In such embodiments, a thickness of P type cladding layer 232 is not greater than 380 nm, for example, the thickness of P type cladding layer 252 is 360 nm.

In some embodiments, a material of first doped P type transition layer 253 is (AlₓGa₁₋ₓ)_{y}In_{1-y}P, where a range of x is from 0.1 to 0.3, and a range of y is from 0.3 to 0.5. For example, x is 0.17 and y is 0.5. In some embodiments, a relationship between x and y is that y is 1 to 5 times x. In some embodiments, thickness of first doped P type transition layer 253 is from 20 nm to 40 nm, for example, 30 nm.

In some embodiments, a material of second doped P type transition layer 254 is AlₓGa₁₋ₓAs, where a range of x is from 0.5 to 0.9, for example, x is 0.6. In some embodiments, a thickness of second doped P type transition layer 254 is from 10 nm to 30 nm, for example, 20 nm.

In some embodiments, a material of doped P type contact layer 255 is GaAs. A thickness of doped P type contact layer 255 is from 10 nm to 30 nm, for example, 20 nm.

In some embodiments, a doping concentration of second doped P type transition layer 254 is greater than a doping concentration of first doped P type transition layer 253. A doping concentration of doped P type contact layer 255 is 1 to 10 times the doping concentration of second doped P type transition layer 254.

In some embodiments, the doping concentration of doped P type contact layer 255 is greater than the doping concentration of second doped P type transition layer 254. Further, in some embodiments, the doping concentration of second doped P type transition layer 254 is 2 to 4 times a doping concentration of first doped P type transition layer 253.

For example, the doping concentration of first doped P type transition layer 253 is greater than 1e¹⁸ cm⁻³, the doping concentration of second doped P type transition layer 254 is in a range of 2e¹⁸ cm⁻³ to 4e¹⁸ cm⁻³, and the doping concentration of doped P type contact layer 255 is greater than 5e¹⁸ cm⁻³.

In some embodiments, referring back to FIG. 2, a thickness of N type semiconductor layer 230 is from 300 nm to 500 nm, and a thickness of P type semiconductor layer 250 is from 400 nm to 600 nm. In some embodiments, a thickness T1 from a top of top conductive layer 260 to a bottom of N type semiconductor layer 230 is not more than 2000 nm.

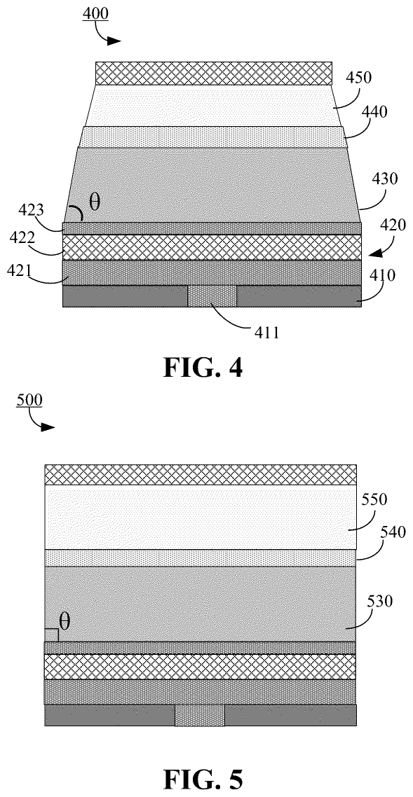

FIG. 4 illustrates a structural diagram showing an exemplary micro LED 400, according to some embodiments of the present disclosure. As shown in FIG. 4, a sidewall of a P type semiconductor layer 450, a light emitting layer 440, and an N type semiconductor layer 430 is inclined. That is, sidewalls of P type semiconductor layer 450, light emitting layer 440, and N type semiconductor layer 430 are along a straight line, and an inclined angle θ is formed between the straight line and a bottom of N type semiconductor layer 430. In some embodiments, the inclined angle θ of the sidewall is from 55 degrees to 65 degrees. A top surface area of P type semiconductor layer 450 is smaller than a top surface area of N type semiconductor layer 430. In some embodiments, a cross section of a top surface of micro LED 400 is a circular, and a diameter of P type semiconductor layer 450 is smaller than a diameter of N type semiconductor layer 430. Accordingly, micro LED 400 has a tapered mesa structure.

FIG. 5 illustrates a structural diagram showing an exemplary micro LED 500, according to some embodiments of the present disclosure. As shown in FIG. 5, a sidewall of a P type semiconductor layer 550, a light emitting layer 540, and an N type semiconductor layer 530 is almost vertical as viewed in FIG. 5. In some embodiments, an inclined angle θ of the sidewall is greater than 85 degrees, for example, between 85 degrees to 90 degrees. Accordingly, micro LED 500 has a vertical mesa structure, which can increase beam angle performance. Also, light emitting area can be larger, thereby increasing the light emission efficiency.

Referring back to FIG. 4, micro LED 400 further including a bonding layer 420 including a first metal bonding layer 421, a transparent bonding layer 422, and a second metal bonding layer 423 from bottom to top. First metal bonding layer 421 and second metal bonding layer 423 are made of metal, which is conductive and non-transparent. In some embodiments, transparent bonding layer 422 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, or the like. N type semiconductor layer 430 is bonded with second metal bonding layer 423, second metal bonding layer 423 is bonded with transparent bonding layer 422, and transparent bonding layer 422 is bonded with first metal bonding layer 421. An IC backplane 410 includes a bottom pad 411 electrically connected to first metal bonding layer 421.

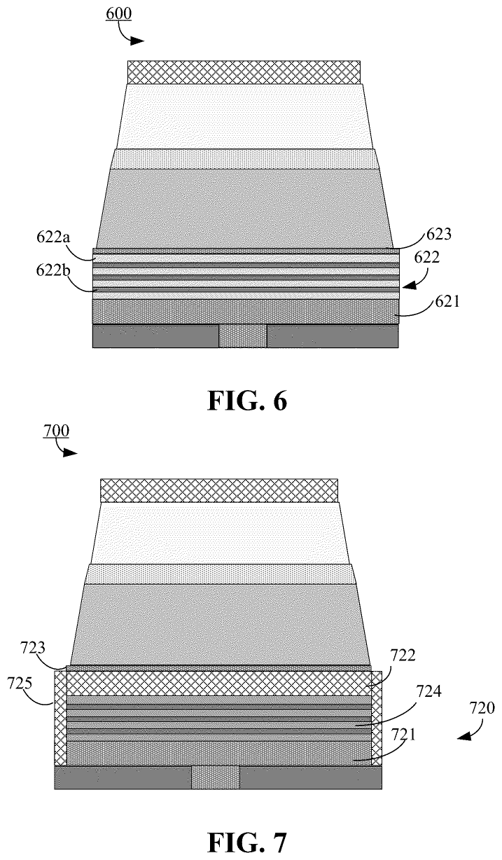

FIG. 6 illustrates a structural diagram showing an exemplary micro LED 600, according to some embodiments of the present disclosure. As shown in FIG. 6, micro LED 600 includes a transparent bonding layer 622 as a distributed Bragg reflection (DBR) layer formed between a first metal bonding layer 621 and a second metal bonding layer 623. The DBR layer includes a plurality of sputter transparent bonding layers 622a and a plurality of porous transparent bonding layers 622b. the plurality of sputter transparent bonding layers 622a and the plurality of porous transparent bonding layers 622b are alternately layered. For example, in some embodiments, a first one of sputter transparent bonding layers 622a is formed on a first metal bonding layer 621, a first one of porous transparent bonding layers 622b is formed on the first one of sputter transparent bonding layers 622a, a second one of sputter transparent bonding layers 622a is formed on the first one of porous transparent bonding layers 622b, a second one of porous transparent bonding layers 622b is formed on the second one of sputter transparent bonding layers 622a, a third one of sputter transparent bonding layers 622a is formed on the second one of porous transparent bonding layers 622b, a third one of porous transparent bonding layers 622b is formed on the third one of sputter transparent bonding layers 622a, a fourth one of sputter transparent bonding layers 622a is formed on the third one of porous transparent bonding layers 622b, and second metal bonding layer 623 is formed on the fourth one of sputter transparent bonding layers 622a. A number of sputter transparent bonding layers 622a could be equal to a number of porous transparent bonding layers 622b plus one, therefore, both first metal bonding layer 621 and second metal bonding layer 623 are bonded with a sputter transparent bonding layer. In some embodiments, the number of sputter transparent bonding layers 622a could be equal to the number of porous transparent bonding layers 622b. Therefore, first metal bonding layer 621 and second metal bonding layer 623 may be bonded with a sputter transparent bonding layer or a porous transparent bonding layer. In some embodiments, the number of sputter transparent bonding layers 622a could be equal to a number of porous transparent bonding layers 622b minus one, therefore, both first metal bonding layer 621 and second metal bonding layer 623 are bonded with a porous transparent bonding layer. It can be understood that the number of sputter transparent bonding layers 622a and the number of porous transparent bonding layers 622b are not limited herein, which can be varied according to actual practice.

In some embodiments, a refractive index of each of sputter transparent bonding layers 622a is greater than 1.7, for example, 1.9, and a refractive index of each of porous transparent bonding layers 622b is less than 1.5. In some embodiments, the sputter transparent bonding layers 622a and porous transparent bonding layers 622b are TCO thin film, for example, one or more of an ITO film, an AZO film, an ATO film, an FTO film, or the like.

FIG. 7 illustrates a structural diagram showing an exemplary micro LED 700, according to some embodiments of the present disclosure. As shown in FIG. 7, a bonding layer 720 includes a second metal bonding layer 723 formed on a transparent bonding layer 722, and a dielectric distributed Bragg reflection (DBR) layer 724 between transparent bonding layer 722 and a first metal bonding layer 721. A side conductive structure 725 is provided surrounding DBR layer 724 for connecting transparent bonding layer 722 with first metal bonding layer 721. In some embodiments, dielectric DBR layer 724 is formed by a plurality of SiO2 layers and a plurality of SiNx layers, and the plurality of SiO2 layers and the plurality of SiNx layers are alternately layered. In some embodiments, a refractive index of each SiO2 layer is 1.45, and a refractive index of each SiNx layer is 2.1. In some embodiments, carriers are injected via side conductive structure 725. Therefore, a current path is formed between transparent bonding layer 722 and first metal bonding layer 721.

FIG. 8 illustrates a structural diagram showing a top view of a micro LED display panel 800, according to some embodiments of the present disclosure. Referring to FIG. 8, micro LED display panel 800 includes a micro LED array 810 and an IC (integrated circuit) backplane 820. Micro LED array 810 is located on IC backplane 820 to form an image display area of micro LED display panel 800. The rest of the area on IC backplane 820 not covered by micro LED array 810 is formed as a non-functional area. IC backplane 820 is formed at the back surface of micro LED array 810 with a part extending outside of, i.e., not covered by, micro LED array 810. Micro LED array 810 includes a plurality of micro LEDs 811 provided in an array. IC backplane 820 is configured to control the plurality of micro LEDs 811. IC backplane 820 may include a bottom pad array (not shown) corresponding to micro LED array 810. The bottom pad array includes a plurality of conductive bottom pads (for example, bottom pad 411 in FIG. 4), and one bottom pad corresponds to one micro LED 811. One micro LED of the plurality of micro LEDs is electrically connected with one bottom pad of the plurality of conductive bottom pads.

In some embodiments, a top conductive layer (for example, top conductive layer 260 in FIG. 2) of the micro LED is interconnected with each of the plurality of micro LEDs. That is, the top conductive layer is continuously formed on a top of micro LED array 810, and connected with every micro LED 811.

In some embodiments, IC backplane 820 further includes a top connected pad 821. The top conductive layer is connected with top connected pad 821, and further may connect to an external circuit.

Each micro LED herein (e.g., micro LED 100 to 700) has a very small volume. The micro LED can be applied in a micro LED display panel. The light emitting area of the micro LED display panel, e.g., micro LED display panel 800, is very small, such as 1 mm×1 mm, 3 mm×5 mm, etc. In some embodiments, the light emitting area is the area of the micro LED array in the micro LED display panel. The micro LED display panel includes one or more micro LED that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 820, is formed at the back surface of micro LED array 810 and is electrically connected with micro LED array 810. The IC backplane acquires signals such as image data from outside via signal lines to control corresponding micro LEDs to emit light or not.

Some embodiments of the present disclosure further provide an epitaxial structure for the micro LED with a P-side structure to improve manufacture processing. In manufacturing the above P-side up structure, a temporary bonding technology is may be used. Therefore, an epitaxial structure is provided.

FIG. 9 illustrates a structural diagram showing an exemplary epitaxial structure 900, according to some embodiments of the present disclosure. As shown in FIG. 9, epitaxial structure 900 for a micro LED includes a substrate 910 provided at a bottom of epitaxial structure 900. Substrate 910 may include N type GaAs for growing epitaxial layers. In some embodiments, a thickness of substrate 910 is not greater than 400 μm, for example, the thickness of substrate 910 is 350 μm.

An etch-stop layer 920 is formed on substrate 910. Etch-stop layer 920 is configured to separate substrate 910 and a device grown thereon. There is no ion doped in etch-stop layer 920. In some embodiments, etch-stop layer 920 includes an alloy of AlGaInP. In some embodiments, a material of etch-stop layer 920 is (AlₓGa₁₋ₓ)_{y}In_{1-y}P, where a range of x is from 0 to 0.3 (for example, x is 0.5), and y is 0.5. In some embodiments, a thickness of etch-stop layer 920 is not greater than 250 nm, for example, the thickness of etch-stop layer 920 is 200 nm.

A P type epitaxial layer 930 is formed on etch-stop layer 920, a light emitting layer 940 is formed on P type epitaxial layer 330, and an N type epitaxial layer 950 is formed on light emitting layer 940. That is, in manufacturing, P type epitaxial layer 930 is grown on etch-stop layer 920, light emitting layer 940 is grown on P type epitaxial layer 930, and N type epitaxial layer 950 is further grown on light emitting layer 940. In some embodiments, a thickness of N type epitaxial layer 950 is from 300 nm to 500 nm, and a thickness of P type epitaxial layer 930 is from 400 nm to 600 nm. In some embodiments, a thickness T2 from a top of N type epitaxial layer 950 to a bottom of P type epitaxial layer 930, i.e., a thickness of the device, is not greater than 1000 nm. In some embodiments, a thickness T3 of epitaxial layers, including etch-stop layer 920, is not greater than 1200 nm.

With this structure, there is no bonding needed for epitaxial structure 900, therefore the manufacturing process is improved and the cost is reduced. After removing substrate 910 and turning over the device, a device with the P-side up structure can be obtained. Then, the device with the P-side up structure can be bonded with an IC backplane to obtain a micro LED structure.

In some embodiments, light emitting layer 940 includes at least one quantum well layer. A thickness of the quantum well layer is from 20 nm to 40 nm, for example, 30 nm. In some embodiments, a material of the quantum well layer is GaInP/(AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, light emitting layer 340 is a multiple quantum well (MQW).

FIG. 10 illustrates a structural diagram showing sub-layers of exemplary epitaxial structure 900, according to some embodiments of the present disclosure. As shown in FIG. 10, N type epitaxial layer 950 further includes an N type spacer layer 951 formed on light emitting layer 940, an N type cladding layer 952 formed on N type spacer layer 951, and a doped N type contact layer 953 formed on N type cladding layer 952. In some embodiments, a material of doped N type contact layer 953 is GaAs, a thickness of doped N type contact layer 953 is from 10 nm to 30 nm. A doping concentration of doped N type contact layer 953 is from 2e¹⁸ cm⁻³ to 1e¹⁹ cm⁻³.

In some embodiments, a material of N type cladding layer 952 is AlₓIn₁₋ₓP, where a range of x is from 0.1 to 0.5, for example, x is 0.5. A thickness of N type cladding layer 952 is not greater than 350 nm, for example, the thickness of N type cladding layer 952 is 320 nm. A doping concentration of N type cladding layer 952 is from 5e¹⁷ cm⁻³ to 1e¹⁸ cm⁻³.

In some embodiments, a material of N type spacer layer 951 is (AlₓGa₁₋ₓ)_{y}In_{1-y}P, where a range of x is from 0.5 to 0.9, and a range of y is from 0.1 to 0.5. For example, x is 0.8, and y is 0.5. In some embodiments, a relationship between x and y is that x is 1 to 2 times y. A thickness of N type spacer layer 951 is from 50 nm to 75 nm, for example, 65 nm.

Still referring to FIG. 10, P type epitaxial layer 930 includes a doped P type contact layer 931 formed on etch-stop layer 920, a second doped P type transition layer 932 formed on doped P type contact layer 931, a first doped P type transition layer 933 formed on second doped P type transition layer 932, a P type cladding layer 934 formed on first doped P type transition layer 933, and a P type spacer layer 935 formed on P type cladding layer 934. In some embodiments, a material of P type spacer layer 935 is (AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, a thickness of P type spacer layer 935 is from 50 nm to 70 nm, for example, 65 nm.

In some embodiments, a material of P type cladding layer 934 is AlₓIn₁₋ₓP, where x is from 0.3 to 0.5, for example, x is 0.5. A thickness of P type cladding layer 934 is not greater than 380 nm, for example, the thickness of P type cladding layer 334 is 360 nm.

In some embodiments, a material of first doped P type transition layer 933 is (AlₓGa₁₋ₓ)_{y}In_{1-y}P, where a range of x is from 0.1 to 0.3, and a range of y is from 0.3 to 0.5. For example, x is 0.17 and y is 0.5. In some embodiments, a relationship between x and y is that y is 1 to 5 times x. A thickness of first doped P type transition layer 933 is from 20 nm to 40 nm, for example, 30 nm.

In some embodiments, a material of second doped P type transition layer 932 is AlₓGa₁₋ₓAs, where a range of x is from 0.5 to 0.9, for example, x is 0.6. In some embodiments, a thickness of second doped P type transition layer 932 is from 10 nm to 30 nm, for example, 20 nm.

In some embodiments, a material of doped P type contact layer 931 is GaAs. A thickness of doped P type contact layer 931 is from 10 nm to 30 nm, for example, 20 nm.

In some embodiments, a doping concentration of second doped P type transition layer 932 is greater than a doping concentration of first doped P type transition layer 933. For example, a doping concentration of doped P type contact layer 931 is 1 to 10 times the doping concentration of second doped P type transition layer 932.

In some embodiments, the doping concentration of doped P type contact layer 931 is greater than the doping concentration of second doped P type transition layer 932. In such embodiments, the doping concentration of second doped P type transition layer 932 is 2 to 4 times a doping concentration of first doped P type transition layer 933.

For example, the doping concentration of first doped P type transition layer 933 is greater than 1e¹⁸ cm⁻³, the doping concentration of second doped P type transition layer 932 is in a range of 2e¹⁸ cm⁻³ to 4e¹⁸ cm⁻³, and doping concentration of doped P type contact layer 931 is greater than 5e¹⁸ cm⁻³.

In one example, referring to FIGS. 9 and 10, the thickness T2 from a top of N type epitaxial layer 950 to a bottom of P type epitaxial layer 930, i.e., a thickness of the device, is 930 nm, and the thickness T3 of epitaxial layers, including etch-stop layer 920, is 1130 nm. In this example, the thickness of doped N type contact layer 953 is 20 nm, the thickness of N type cladding layer 952 is 320 nm, the thickness of N type spacer layer 951 is 65 nm, the thickness of light emitting layer 940 is 30 nm, the thickness of P type spacer layer 935 is 65 nm, the thickness of P type cladding layer 934 is 360 nm, the thickness of first doped P type transition layer 933 is 30 nm, the thickness of second doped P type transition layer 932 is 20 nm, the thickness of doped P type contact layer 931 is 20 nm, the thickness of etch-stop layer is 200 nm, and the thickness of substrate is 350 μm.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED comprising:
a bonding layer;
an N type semiconductor layer formed on the bonding layer;
a light emitting layer formed on the N type semiconductor layer;
a P type semiconductor layer formed on the light emitting layer; and
a top conductive layer formed on the P type semiconductor layer.

2. The micro LED according to claim 1, wherein the light emitting layer comprises at least one quantum well layer.

3. The micro LED according to claim 2, wherein a thickness of the quantum well layer is from 20 nm to 40 nm.

4. The micro LED according to claim 2, wherein the quantum well layer is GaInP/(AlₓGa₁₋ₓ)_{y}In_{1-y}P, wherein a range of x is from 0.5 to 0.9, and a range of y is from 0.3 to 0.5.

5. The micro LED according to claim 4, wherein x is 1 to 2 times y.

6. The micro LED according to claim 1, wherein the N type semiconductor layer comprises a doped N type contact layer, an N type cladding layer, and an N type spacer layer from bottom to top.

7. The micro LED according to claim 6, wherein a doping concentration of the doped N type contact layer is from 2e¹⁸ cm⁻³ to 1e¹⁹ cm⁻³.

8. The micro LED according to claim 6, wherein the N type cladding layer is AlₓIn₁₋ₓP, wherein a range of x is from 0.1 to 0.5.

9. The micro LED according to claim 6, wherein the N type spacer layer is (AlₓGa₁₋ₓ)yIn_{1-y}P, wherein a range of x is from 0.5 to 0.9, and a range of y is from 0.1 to 0.5.

10. The micro LED according to claim 9, wherein x is 1 to 2 times y.

11. The micro LED according to claim 1, wherein the P type semiconductor layer further comprises a P type spacer layer, a P type cladding layer, a first doped P type transition layer, a second doped P type transition layer, and a doped P type contact layer from bottom to top.

12. The micro LED according to claim 11, wherein, the P type spacer layer is (AlₓGa₁₋ₓ)_{y}In_{1-y}P, wherein a range of x is from 0.5 to 0.9, and a range of y is from 0.3 to 0.5.

13. The micro LED according to claim 12, wherein x is 1 to 2 times y.

14. The micro LED according to claim 11, wherein the P type cladding layer is AlₓIn₁₋ₓP, wherein x is from 0.3 to 0.5.

15. The micro LED according to claim 11, wherein the first doped P type transition layer is (AlₓGa₁₋ₓ)_{y}In_{1-y}P, wherein a range of x is from 0.1 to 0.3, and a range of y is from 0.3 to 0.5.

16. The micro LED according to claim 15, wherein y is 1 to 5 times x.

17. The micro LED according to claim 11, wherein the second doped P type transition layer is AlₓGa₁₋ₓAs, wherein a range of x is from 0.5 to 0.9.

18. The micro LED according to claim 11, wherein the doped P type contact layer is GaAs.

19. The micro LED according to claim 11, wherein a doping concentration of the second doped P type transition layer is greater than a doping concentration of the first doped P type transition layer.

20. The micro LED according to claim 19, wherein a doping concentration of the doped P type contact layer is 1 to 10 times a doping concentration of the second doped P type transition layer.

21. The micro LED according to claim 11, wherein a doping concentration of the doped P type contact layer is greater than a doping concentration of the second doped P type transition layer.

22. The micro LED according to claim 21, wherein the doping concentration of the second doped P type transition layer is 2 to 4 times a doping concentration of the first doped P type transition layer.

23. The micro LED according to claim 1, wherein a thickness of the N type semiconductor layer is from 300 nm to 500 nm; and a thickness of the P type semiconductor layer is from 400 nm to 600 nm.

24. The micro LED according to claim 23, wherein a thickness from a top of the top conductive layer to a bottom of the N type semiconductor layer is not more than 2000 nm.

25. The micro LED according to claim 1, wherein a sidewall of the P type semiconductor layer, the light emitting layer, and the N type semiconductor layer is inclined.

26. The micro LED according to claim 25, wherein an inclined angle of the sidewall is from 55 degrees to 65 degrees.

27. The micro LED according to claim 25, wherein an inclined angle of the sidewall is greater than 85 degrees.

28. The micro LED according to claim 25, wherein a top surface area of the P type semiconductor layer is smaller than a top surface area of the N type semiconductor layer.

29. The micro LED according to claim 1, wherein a sidewall of the micro LED is vertical.

30. The micro LED according to claim 1, wherein the bonding layer further comprises a first metal bonding layer, a transparent bonding layer, and a second metal bonding layer from bottom to top.

31. The micro LED according to claim 30, wherein the transparent bonding layer comprises a plurality of sputter transparent bonding layers and a plurality of porous transparent bonding layers, the plurality of sputter transparent bonding layers and the plurality of porous transparent bonding layers being alternated layered.

32. The micro LED according to claim 30, the bonding layer further comprising:
a dielectric distributed Bragg reflection (DBR) layer between the transparent bonding layer and the first metal bonding layer; and
a side conductive structure provided on a side of the DBR layer for connecting the transparent bonding layer with the first metal bonding layer.

33. A micro LED display panel comprises:
an integrated circuit (IC) backplane comprising a bottom pad array, the bottom pad array comprising a plurality of conductive bottom pads; and
a micro LED array formed on the IC backplane, the micro LED array comprising a plurality of micro LEDs;
wherein one micro LED of the plurality of micro LEDs is electrically connected with one bottom pad of the plurality of conductive bottom pads; and the micro LED comprises:
a bonding layer;
an N type semiconductor layer formed on the bonding layer;
a light emitting layer formed on the N type semiconductor layer;
a P type semiconductor layer formed on the light emitting layer; and
a top conductive layer formed on the P type semiconductor layer.

34. The micro LED display panel according to claim 33, wherein respective top conductive layers of the plurality of micro LEDs are interconnected.

35. The micro LED display panel according to claim 34, wherein the IC backplane further comprises a top connected pad, and the respective top conductive layers are connected with the top connected pad of the IC backplane.

36. An epitaxial structure for a micro LED comprising:
a substrate;
an etch stop layer formed on the substrate;
a P type epitaxial layer formed on the etch stop layer;
a light emitting layer formed on the P type epitaxial layer; and
an N type epitaxial layer formed on the light emitting layer.

37. The epitaxial structure according to claim 36, wherein the light emitting layer comprises at least one quantum well layer.

38. The epitaxial structure according to claim 37, wherein a thickness of the quantum well layer is from 20 nm to 40 nm.

39. The epitaxial structure according to claim 37, wherein the quantum well layer is GaInP/(AlₓGa₁₋ₓ)_{y}In_{1-y}P, wherein a range of x is from 0.5 to 0.9, and a range of y is from 0.3 to 0.5.

40. The epitaxial structure according to claim 39, wherein x is 1 to 2 times y.

41. The epitaxial structure according to claim 36, wherein the N type epitaxial layer comprises:
an N type spacer layer formed on the light emitting layer;
an N type cladding layer formed on the N type spacer layer; and
a doped N type contact layer formed on the N type cladding layer.

42. The epitaxial structure according to claim 41, wherein a doping concentration of the doped N type contact layer is from 2e¹⁸ cm⁻³ to 1e¹⁹ cm⁻³.

43. The epitaxial structure according to claim 41, wherein the N type cladding layer is AlₓIn₁₋ₓP, wherein a range of x is from 0.1 to 0.5.

44. The epitaxial structure according to claim 41, wherein the N type spacer layer is (AlₓGa₁₋ₓ)_{y}In_{1-y}P, wherein a range of x is from 0.5 to 0.9, and a range of y is from 0.1 to 0.5.

45. The epitaxial structure according to claim 44, wherein x is 1 to 2 times y.

46. The epitaxial structure according to claim 36, wherein the P type epitaxial layer comprises:
a doped P type contact layer formed on the etch stop layer;
a second doped P type transition layer formed on the doped P type contact layer;
a first doped P type transition layer formed on the second doped P type transition layer;
a P type cladding layer formed on the first doped P type transition layer; and
a P type spacer layer formed on the P type cladding layer.

47. The epitaxial structure according to claim 46, wherein the P type spacer layer is (AlₓGa₁₋ₓ)_{y}In_{1-y}P, wherein a range of x is from 0.5 to 0.9, and a range of y is from 0.3 to 0.5.

48. The epitaxial structure according to claim 47, wherein x is 1 to 2 times y.

49. The epitaxial structure according to claim 46, wherein the P type cladding layer is AlₓIn₁₋ₓP, wherein x is from 0.3 to 0.5.

50. The epitaxial structure according to claim 46, wherein the first doped P type transition layer is (AlₓGa₁₋ₓ)_{y}In_{1-y}P, wherein a range of x is from 0.1 to 0.3, and a range of y is from 0.3 to 0.5.

51. The epitaxial structure according to claim 50, wherein y is 1 to 5 times x.

52. The epitaxial structure according to claim 46, wherein the second doped P type transition layer is AlₓGa₁₋ₓAs, wherein a range of x is from 0.5 to 0.9.

53. The epitaxial structure according to claim 46, wherein the doped P type contact layer is GaAs.

54. The epitaxial structure according to claim 46, wherein a doping concentration of the second doped P type transition layer is greater than a doping concentration of the first doped P type transition layer.

55. The epitaxial structure according to claim 54, wherein a doping concentration of the doped P type contact layer is 1 to 10 times the doping concentration of the second doped P type transition layer.

56. The epitaxial structure according to claim 46, wherein a doping concentration of the doped P type contact layer is greater than a doping concentration of the second doped P type transition layer.

57. The epitaxial structure according to claim 56, wherein the doping concentration of the second doped P type transition layer is 2 to 4 times a doping concentration of the first doped P type transition layer.

58. The epitaxial structure according to claim 36, wherein a thickness of the N type epitaxial layer is from 300 nm to 500 nm, and a thickness of the P type epitaxial layer is from 400 nm to 600 nm.

59. The epitaxial structure according to claim 58, wherein a thickness from a top of the N type epitaxial layer to a bottom of the P type epitaxial layer is not greater than 1000 nm.
